(19) United States
(12) Patent Application Publication
(10) Pub. No.: US 2002/0187614 A1
(43) Pub. Date: Dec. 12, 2002

(54) Methods for forming ultrashallow junctions with low sheet resistance

(76) Inventor: Daniel F. Downey, Magnolia, MA (US)

Correspondence Address: Gary L. Loser. Esq., Varian Semicoductor Equipment Associates, Inc., 35 Dory Road, Gloucester, MA, 01930, US

(21) Appl. No.: 09/835,653

(22) Filed: Apr. 16, 2001

(51) Int. Cl. H01L 21/26; H01L 21/42; H01L 21/425; H01L 21/22; H01L 29/36; H01L 29/207; H01L 31/0288; H01L 21/76; H01L 21/265; H01L 21/38; H01L 29/167; H01L 29/227

(52) U.S. Cl. 438/407; 257/917; 257/655; 257/607; 257/610; 257/611; 438/520; 438/528; 438/548; 438/918; 438/514

(57) ABSTRACT

Methods and apparatus are provided for forming ultrashallow junctions in semiconductor wafers. The method includes the step of introducing into a shallow surface layer of a semiconductor wafer a dopant material that is selected to form charge carrier complexes, such as exciton complexes, which produce at least two charge carriers per complex. The semiconductor wafer containing the dopant material may be processed, such as by thermal processing, to form the charge carrier complexes. The charge carrier complexes are interstitial and therefore are not subject to the limitations imposed by the electrical solubility limits resulting from incorporation into substitutional sites. Thus, low sheet resistance can be obtained.

### FIELD OF THE INVENTION

This invention relates to methods for forming ultrashallow junctions in semiconductor wafers and, more particularly, to methods for forming ultrashallow junctions having low sheet resistance by the formation and stabilization of charge carrier complexes, such as exciton complexes, in a shallow surface layer of the semiconductor wafer. The charge carrier complexes produce at least two charge carriers per complex.

### BACKGROUND OF THE INVENTION

A well-known trend in the semiconductor industry is toward smaller, higher speed devices. In particular, both the lateral dimensions and the depth of features in semiconductor devices are decreasing. State of the art semiconductor devices require junction depths less than 1,000 angstroms and may eventually require junction depths on the order of 200 angstroms or less.

Ion implantation is a standard technique for introducing conductivity-altering dopant materials into semiconductor wafers. In a conventional ion implantation system, known as a beamline ion implanter, a desired dopant material is ionized in an ion source, the ions are accelerated to form an ion beam of prescribed energy, and the ion beam is directed at the surface of the wafer. The energetic ions in the beam penetrate into the bulk of the semiconductor material and are imbedded into the crystalline lattice of the semiconductor material.

Plasma doping systems may be used for forming shallow junctions in semiconductor wafers. In a plasma doping system, a semiconductor wafer is placed on a conductive platen which functions as a cathode. An ionizable gas containing the desired dopant material is introduced into the chamber, and a voltage pulse is applied between the platen and an anode or the chamber walls, causing formation of a plasma having a plasma sheath at the surface of the wafer. The applied voltage pulse causes ions in the plasma to cross the plasma sheath and to be implanted into the wafer. The depth of implantation is related to the voltage applied between the wafer and the anode.

The implanted depth of the dopant material is determined, at least in part, by the energy of the ions implanted into the semiconductor wafer. Shallow junctions are obtained with low implant energies. However, the annealing process that is used for activation of the implanted dopant material causes the dopant material to diffuse from the implanted region of the semiconductor wafer. As a result of such diffusion, junction depths are increased by annealing. To counteract the increase in junction depth produced by annealing, the implant energy may be decreased, so that a desired junction depth after annealing is obtained. This approach provides satisfactory results, except in the case of very shallow junctions. A limit is reached as to the junction depth that can be obtained by decreasing implant energy, due to the diffusion of the dopant material that occurs during annealing. In addition, conventional ion implanters typically operate inefficiently at very low implant energies.

In addition to shallow junction depths, implanted regions are required to have low sheet resistance for proper operation of the devices being fabricated on the semiconductor wafer. The sheet resistance depends in part on the effectiveness of the activation process.

These factors have presented difficulties in achieving ultrashallow junctions having low sheet resistance.

Accordingly, there is a need for methods for fabricating ultrashallow junctions having low sheet resistance in semiconductor wafers.

### SUMMARY OF THE INVENTION

The invention involves the formation and stabilization of charge carrier complexes, such as exciton complexes, which are electron-hole pairs bound to dopant and/or other impurities. These exciton complexes can be formed by the introduction of two dopant species which can chemically bond or by the introduction of one dopant species which can chemically bond with the host material or impurities/defects in the host material. The dopant materials are incorporated in a shallow surface layer, typically 500 angstroms or less, and are chemically bonded together, with or without thermal treatment and without significant diffusion, to form exciton complexes. The exciton complexes form because the coulombic forces of the shallow layers are large and assist in the creation of bound electron-hole pairs (excitons). The exciton complexes generally are interstitial and, hence, are not subject to the limitations imposed by the electrical solubility limits resulting from incorporation into substitutional sites. Low sheet resistance can thus be obtained by an increase in dose. The dissociation of the exciton about the complex is the mechanism that provides the free carriers for control of conductivity.

The activation process provides two charge carriers per complex rather than one charge carrier per substitutional atom. One charge carrier is the common number for charge carrier generation from standard silicon conductivity mechanisms. The type (p or n) of the exciton layer is determined by the position of the Fermi level within the band gap and the population of states as determined by the incorporated impurities. In these cases, methods to create p-type layers with p-type dopants and n-type layers with n-type dopants are emphasized. It is possible using this approach to create sub 200 angstroms n or p-type junctions with sheet resistance values less than 100 ohms per square.

According to a first aspect of the invention, a method is provided for forming an ultrashallow junction in a semiconductor wafer. The method comprises the steps of introducing into a shallow surface layer of the semiconductor wafer a dopant material that is selected to form charge carrier complexes which produce at least two charge carriers per complex, and processing the semiconductor wafer containing the dopant material to form the charge carrier complexes. The charge carrier complexes may be an exciton complexes.

In one embodiment, the dopant material comprises two species selected to form the charge carrier complexes. In another embodiment, the dopant material comprises a compound containing two species selected to form the charge carrier complexes. In a further embodiment, the dopant material is selected to chemically bond with atoms of the semiconductor wafer to form the charge carrier complexes. By way of example, the dopant material may be selected from the group consisting of B—F, B—Ge, B—Si, P—F, P—Ge, P—Si, As—F, As—Ge and As—Si.

In one embodiment, the dopant material may be introduced into the semiconductor wafer by ion implantation. In another embodiment, the dopant material may be introduced into the semiconductor wafer by plasma doping. In another embodiment, the dopant material may be introduced into the semiconductor wafer by gas phase doping. In further embodiments, the dopant material may be introduced into the semiconductor wafer as part of an expitaxial deposition or chemical vapor deposition step. In yet another embodiment, the dopant material may be introduced into the semiconductor wafer by forming alternating mono or atomic layers of dopant material and host material using one of the techniques described above.

The step of processing the semiconductor wafer may comprise thermal processing. In one embodiment, the processing step comprises laser annealing of the shallow surface layer. In another embodiment, the processing step comprises rapid thermal processing. In a further embodiment, the processing step may comprise solid-phase epitaxy. In other embodiments, the processing step may comprise microwave annealing, radio frequency annealing, shock wave annealing or furnace annealing.

The above techniques for introducing the dopant material into the semiconductor wafer and for processing the semiconductor wafer are given by way of example only and are not limiting as to the scope of the invention. Furthermore, the above techniques may be used separately or in combination.

According to another aspect of the invention, a semiconductor device is provided. The semiconductor device comprises a semiconductor substrate and a shallow surface layer of the semiconductor substrate containing charge carrier complexes which produce at least two charge carriers per complex. The charge carriers are dissociated from the complexes at room temperature and are available to participate in electrical conduction.

### BRIEF DESCRIPTION OF THE DRAWINGS

For a better understanding of the present invention, reference is made to the accompanying drawings, which are incorporated herein by reference and in which:

FIG. 1 is a graph of sheet resistance Rₛ in ohms per square as a function of junction depth in nanometers for various implant and anneal technologies;

FIG. 2A is a graph of boron concentration in atoms in cubic centimeter as a function of junction depth in angstroms for various boron doses in silicon wafers, after laser annealing;

FIG. 2B is a table that lists parameters associated with the wafers represented by FIG. 2A;

FIG. 3A is a graph of concentration in atoms per cubic centimeter as a function of depth in angstroms for boron and germanium in a silicon wafer, after laser annealing;

FIG. 3B is a table that lists parameters associated with the wafer represented by FIG. 3A;

FIG. 4A is a graph of concentration in atoms per cubic centimeter as a function of depth in angstroms for boron and germanium in a silicon wafer, after laser annealing; and

FIG. 4B is a table that lists parameters associated with the wafer represented by FIG. 4A.

### DETAILED DESCRIPTION

According to one aspect of the present invention, methods are provided for forming ultrashallow junctions in semiconductor wafers. According to another aspect of the invention, semiconductor devices having ultrashallow junctions are provided. The methods and devices involve the formation of charge carrier complexes which produce at least two charge carriers per complex. The charge carrier complex includes two or more atoms which are chemically bonded together. Examples include boron bonded to silicon, boron bonded to germanium, and boron bonded to fluorine. The charge carrier complex further includes an electron-hole pair bound to the chemically bonded atoms. At room temperature, the electron-hole pairs are dissociated from the complexes and are available to participate in electrical conduction. An example of a charge carrier complex is the exciton complex described, for example, by R. Knox in Theory of Excitons, Academic Press, New York (1963).

The charge carrier complexes may be formed by introducing into a shallow surface layer of the semiconductor wafer two dopant species which can chemically bond or one dopant species which can chemically bond with the host material or impurities/defects in the host material. Atoms of the dopant species are chemically bonded together to form charge carrier complexes, such as exciton complexes. The exciton complexes are typically interstitial and are not subject to the limitations imposed by the electrical solubility limits resulting from incorporation into subsititutional sites. The dissociation of the exciton from the charge carrier complexes provides free charge carriers, which result in low sheet resistance.

Following activation, each charge carrier complex provides two charge carriers, corresponding to the electron-hole pair. By contrast, typical ion implantation processes provide one charge carrier per dopant atom. In practice, a semiconductor wafer may include both charge carrier complexes and conventional substitutional dopant atoms.

It is customary to express activation of implanted dopant materials as a percentage, defined as the number of charge carriers divided by the number of dopant atoms (dose). In conventional semiconductor conduction mechanisms, activation is necessarily less than 100%, since each dopant atom contributes, at most, one charge carrier. However, where conduction results in whole or in part from charge carrier complexes as described above, activation may exceed 100%, and may approach 200%, where the percent activation is defined in this case as the number of charge carriers divided by the number of dopant atoms and the number of charge carriers may approach two per dopant atom. The practical effect is that more charge carriers are available for conduction, and sheet resistance is reduced in comparison with conventional conduction mechanisms.

As noted above, the charge carrier complexes can be formed by the introduction into the semiconductor wafer of two dopant species which can chemically bond or by the introduction into the semiconductor wafer of one dopant species which can chemically bond with the host material or impurities/defects in the host material. Examples of dopant materials that may bond to form charge carrier complexes in silicon include, but are not limited to, boron-fluorine (B—F), boron-germanium (B—Ge), boron-silicon (B—Si), phosphorous-fluorine (P—F), phosphorous-germanium (P—Ge), phosphorous-silicon (P—Si), arsenic-fluorine (As—F), arsenic-germanium (As—Ge) and arsenic-silicon (As—Si). Thus, for example, boron-fluorine charge carrier complexes may be formed by the introduction of boron ions and fluorine ions or by the introduction of BF₂. Similarly, boron-germanium charge carrier complexes can be formed by the introduction of boron ions and germanium ions. For optimum chemical bonding of the dopant species, the number of atoms of the two dopant species should be approximately equal, as described below.

In one embodiment, the dopant material may be introduced into the semiconductor wafer using a beamline ion implanter operating at ultra low energy. In another embodiment, the dopant material may be introduced into the semiconductor wafer using a plasma doping system. In each case, the ion energy is adjusted to implant the dopant material into a shallow surface layer of the semiconductor wafer, typically having a depth of 500 angstroms or less. In another embodiment, the dopant material may be introduced into the semiconductor wafer by gas phase doping. In further embodiments, the dopant material may be introduced into the semiconductor wafer as part of an expitaxial deposition or chemical vapor deposition step. In yet another embodiment, the dopant material may be introduced into the semiconductor wafer by forming alternating mono or atomic layers of dopant material and host material, such as boron and silicon, boron and germanium, or boron, silicon and gennanium. The alternating layers may be formed by any of the deposition or implant techniques described above. It will be understood that these techniques for introducing dopant material into the semiconductor wafer are given by way of example only and are not limiting as to the scope of the invention.

A processing step may be required following introduction of the dopant materials to cause the chemical bonding which results in formation of the charge carrier complexes. The processing step typically involves thermal processing. In some cases, appropriate conditions for formation of the charge carrier complexes are produced during introduction of the dopant materials. For example, plasma doping may be performed at elevated temperatures suitable for formation of charge carrier complexes.

The wafer containing the dopant material may be processed by laser annealing to form the charge carrier complexes. In one embodiment utilizing laser annealing, the wafer is pre-amorphized to a specified depth, and the laser annealing step produces melting of the pre-amorphized layer and formation of the charge carrier complexes in the layer which was melted. In another embodiment utilizing laser annealing, the wafer containing the dopant material may be processed by sub-melt laser annealing and low temperature rapid thermal annealing, as described in U.S. application Ser. No. 09/638,410, which is hereby incorporated by reference.

In another embodiment, the semiconductor wafer containing the dopant material may be processed by rapid thermal processing (RTP) at temperatures selected to form the charge carrier complexes without significant diffusion. For example, a spike anneal may be utilized. Preferably, rapid thermal processing is followed by rapid cooling of the wafer in order to avoid dissociation of the complexes.

In yet another approach, solid phase epitaxy (SPE) and a low temperature anneal may be utilized for formation of the charge carrier complexes. By way of example, an amorphizing implant (e.g. silicon or germanium at 5E14 to 1E15 ions per square centimeter) is first performed, followed by the dopant implant of similar dose. Then the damaged layer is regrown at a temperature of 500° to 700° C. for 5 to 30 minutes. This produces both charge carrier complexes and substitutional dopants.

Other suitable techniques for processing the semiconductor wafer containing the dopant material include, but are not limited to, microwave annealing, RF annealing, shock wave annealing and furnace annealing.

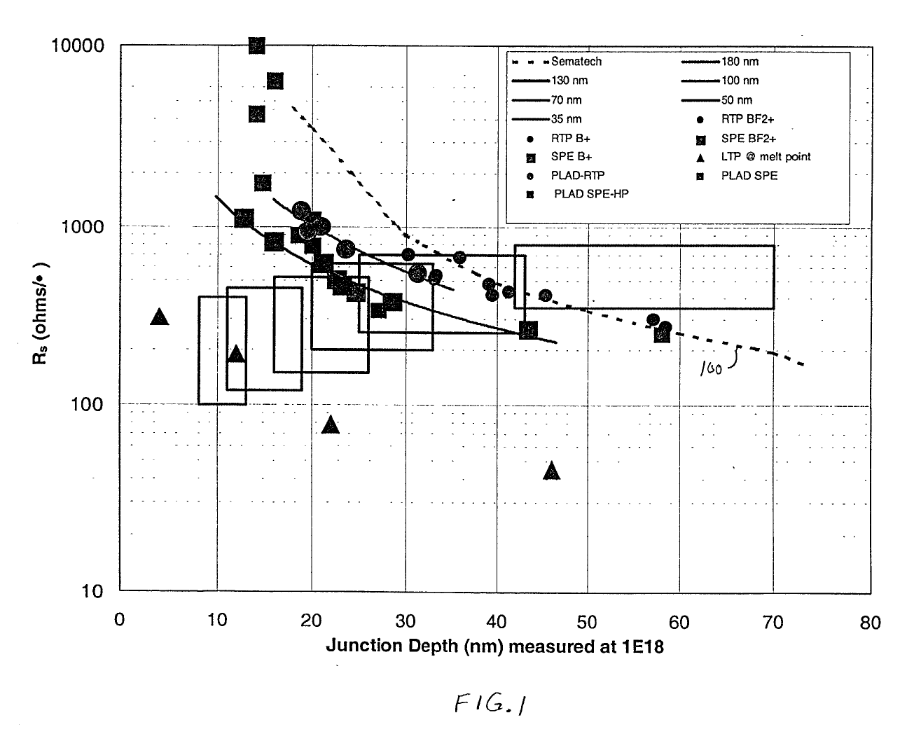

A graph of sheet resistance Rₛ in ohms per square as a function of junction depth in nanometers, measured at a dopant concentration of IE18, for various implant and anneal processes is shown in FIG. 1. The notation “1E18” represents a dopant concentration of 1×10¹⁸ atoms per cubic centimeter. A dashed curve 100 indicates the limit of junction depth and sheet resistance that is predicted by the solid solubility limit of dopant materials in silicon for a standard implant dopant profile. Results below and to the left of curve 100 are obtained by the formation of charge carrier complexes.

FIG. 1 illustrates the 1999 ITRS Rₛ versus Xⱼ roadmap requirement for various generations of devices, illustrated by boxes 102, 104, 106, 108, 110 and 112 for 180, 130, 100, 70, 50 and 35 nanometer devices, respectively. In order to satisfy these requirements, successively lower values of Rₛ and Xⱼ are required. Standard conductivity mechanisms (single charge carrier substitutional dopants) will not meet these requirements. Instead, charge carrier mechanisms as described herein, which involve two or more charge carriers and which do not have the limitations of solid solubility, will be required. Techniques used to get below curve 100 are illustrated in FIG. 1. Those techniques include a) fast RTP anneals of boron and BF₂ (beamline implants and plasma doping), b) SPE and c) laser annealing. In addition, microwave and RF anneals and epitaxial and gas phase doped layers are expected to give results below curve 100.

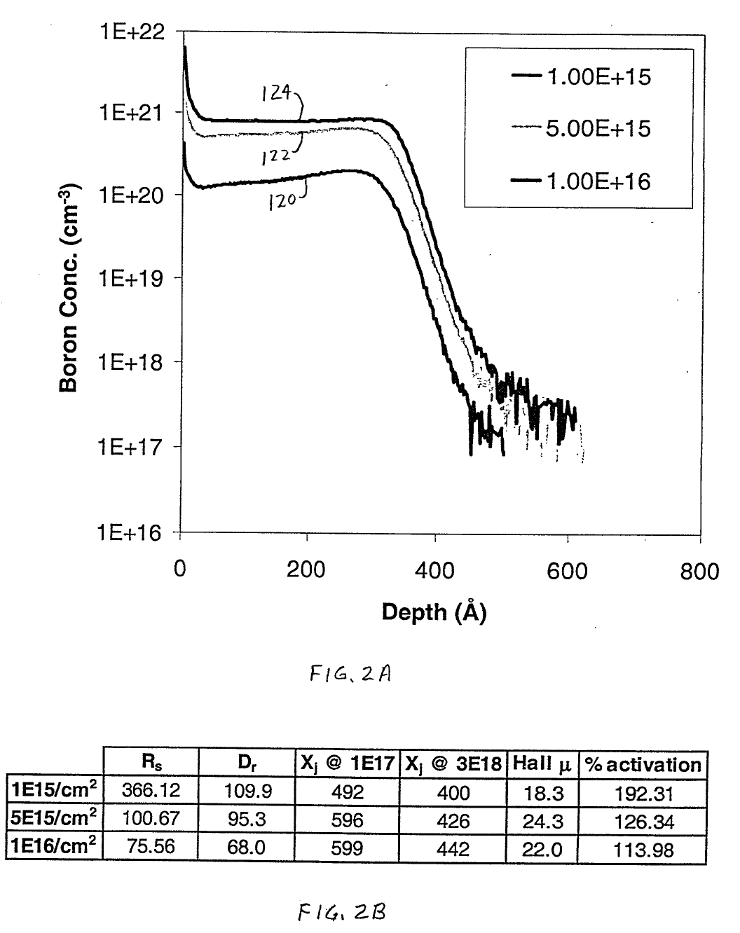

As one example of how to form these complexes, a laser anneal of boron and germanium implants is used. FIG. 2A is a graph of boron concentration in atoms per cubic centimeter as a function of depth in angstroms for boron implants in silicon wafers at various doses. In each case, boron ions were implanted at an energy of 250 electron volts in a Varian VIISion ULE ion implant system. The wafers were pre-amorphized by an implant of germanium ions at an energy of 20 KeV and a dose of 1E15. The implanted wafers were processed by laser annealing to melt the pre-amorphized regions. In FIG. 2A, curves 120, 122 and 124 represent boron doses of 1.00E15, 5.00E15 and 1.00E16, respectively. Curves 120, 122 and 124 were obtained by secondary ion mass spectroscopy (SIMS) measurement of the dopant concentration. FIG. 2B summarizes measurements of sheet resistance Rₛ, as measured by four point probe, obtained dose Dᵣ, as measured by SIMS, junction depth Xⱼ at a boron concentration of 1E17, junction depth Xⱼ at a boron concentration of 3E18, Hall mobility, as measured by the Hall effect, and percent activation, as determined from the electrical carrier concentration, measured by the Hall effect, and the boron dose, measured by SIMS. In each case, the percent activation of boron exceeds 100%, thereby indicating the presence of charge carrier complexes as described above. The percent activation of boron is highest where the boron and germanium doses were equal.

It should be noted that the sheet resistance Rₛ value did continue to decrease with increasing boron dose, even though the percent activation decreased because of the limit of germanium at a dose of 1E15. An increase of germanium dose to match the boron dose would decrease the sheet resistance Rₛ even further and increase the percent activation for the 1E16 boron dose.

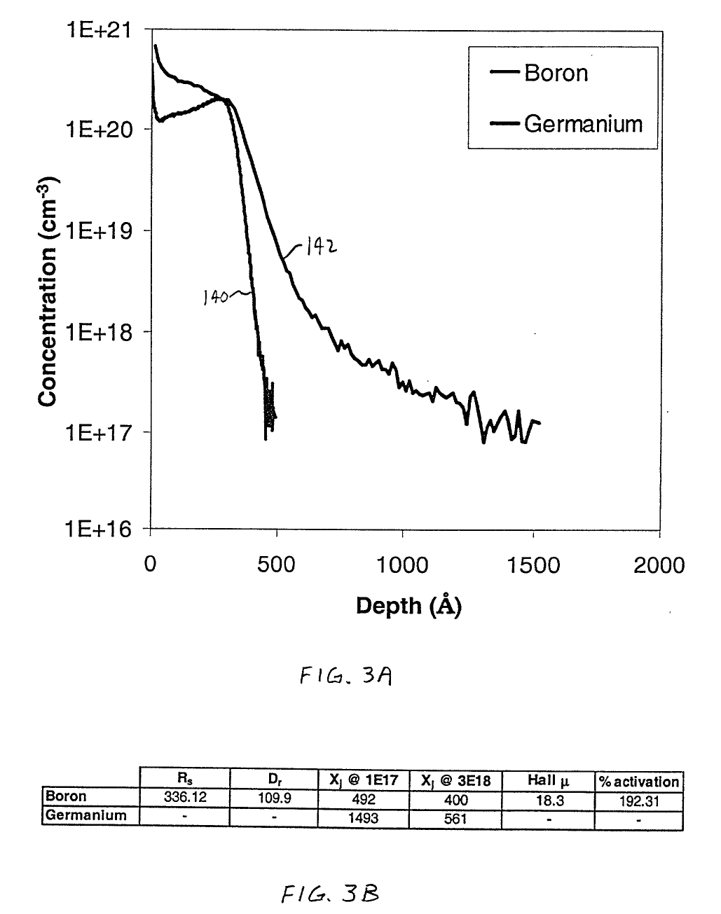

FIG. 3A is a graph of concentration in atoms per cubic centimeter as a function of depth in angstroms for boron and germanium implants in the silicon wafer represented by curve 120 in FIG. 2A. Curve 140 represents boron concentration as a function of depth, and curve 142 represents germanium concentration as a function of depth. Curves 140 and 142 were obtained by SIMS measurements of dopant concentration. FIG. 3B indicates that percent activation of boron approaches 200%. This results from the fact that sufficient germanium is available to react with the boron to form boron-germanium charge carrier complexes.

The example of FIGS. 3A and 3B illustrates the mechanisms and a method to optimize the process. Matching the depth and dose profiles of the dopant species that form the charge carrier complexes (boron and germanium in this example) optimizes the number of complexes that can form. Increasing the doses of boron and germanium to the chemical bonding limit well in excess of the solid solubility limit and matching these profiles in depth optimizes the number of complexes (boron-germanium in this example) that can form. In the case of laser annealing, the preamorphization germanium dose defines the melt zone and sets the junction depth.

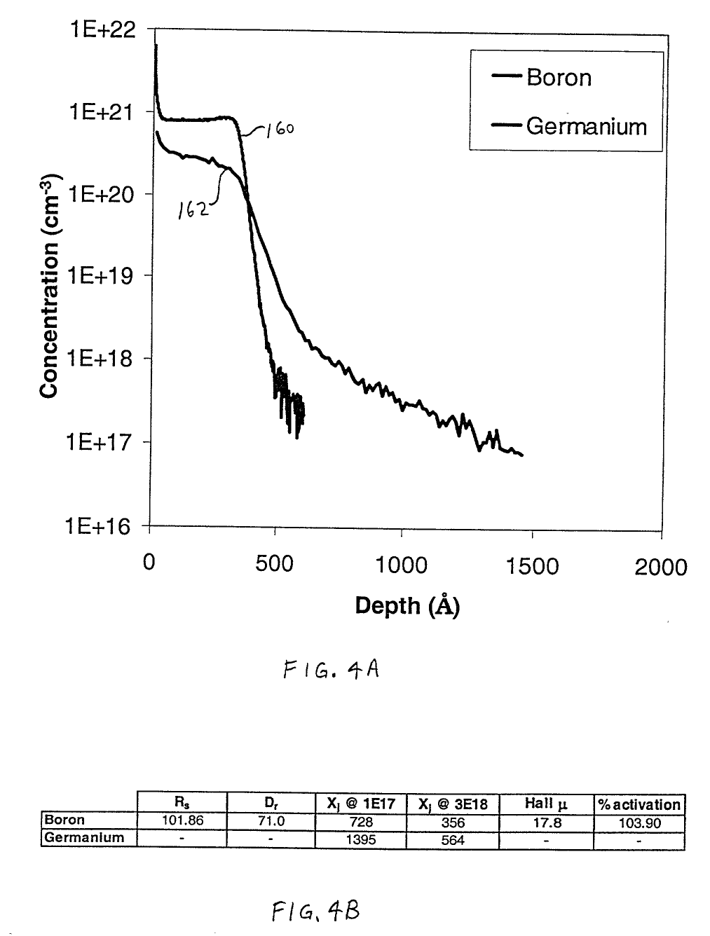

FIG. 4A is a graph of dopant concentration in atoms per cubic centimeter as a function of depth in angstroms for boron and germanium implants in a silicon wafer. In the example of FIG. 4A, boron ions were implanted at an energy of 250 electron volts and a dose of 5E15 in a Varian VIISion ULE ion implant system. The wafer was pre-amorphized with an implant of germanium ions at an energy of 20 KeV and a dose of 1E15. The wafer was processed by laser annealing to melt the pre-amorphized region. In FIG. 4A, curve 160 represents boron concentration as a function of depth, and curve 162 represents germanium concentration as a function of depth. Curves 160 and 162 were obtained by SIMS measurements of dopant concentration. As shown in FIG. 4B, the percent activation of boron is only slightly above 100%, indicating that the number of charge carrier complexes formed was limited by the germanium dose. This is expected, since the number of germanium atoms available for chemical bonding to the boron atoms is low in comparison with the number of boron atoms. If the germanium dose was increased to about 5E15, the activation would be increased to about 200%.

In FIGS. 4A and 4B, the sheet resistance is low at 101.86 ohms per square, but could be made lower by increasing the germanium dose. It is expected that the sheet resistance can be minimized and the activation can be increased to about 200% by matching the boron and germanium SIMS profiles, i.e., matching the dopant profiles in depth and in dose.

A technique is now described for calculating percent activation in the case where charge carrier complexes are formed. It will be understood that a wafer is likely to include both conventional single charge carrier activation and formation of charge carrier complexes. First, the percent overlap of the two species which form the charge carrier complexes is determined. The percent overlap depends on the depth and the dose of the two species and may be determined by SIMS. Where the depths and doses of the two species, such as boron and germanium, are equal, the percent overlap may approach 100%. Next, a chemical reaction percent is determined for the two species in the host material. The chemical reaction percent for boron and germanium in silicon processed by laser annealing may approach 100%. The percent activation is then given by:

percent activation=2Rx+A(100−Rx)

where

R=percent chemical reaction of species/100%

A=percent conventional activation/100% (single charge carriers)

x=percent overlap of species

Rx=percent of charge carrier complexes

100−Rx=percent of single charge carriers

Examples of calculated values of percent activation for different species are compared with measured values of percent activation in Table 1 below.

| | Dose | Energy | Measured % | Calculated % |
|---|---|---|---|---|
| Species | (1E15) | (keV) | Activation | Activation |
| B/Si 5keV | 1.0 | 0.25 | 136.55 | 140.00* |
| B/Ge (20keV) | 1.0 | 0.25 | 192.31 | 190.2 |
| BF₂/Si* 10keV | 10.0 | 1.1 | 138.81 | 140.0 |
| SPE layerˆ | 0.5 | 0.5 | 179 | 165 |
| B/Ge | | | | |

*1E15 B and Si appear to react to 40% only, B and Ge can react up to 100%
ˆ Higher Dose SPE does not lower Rₛ proportionally (limited reactivity)

From the above, it may be observed that the percent activation may be increased by increasing the overlap of the two species in the wafer. In particular, the percent activation may be increased by matching the depth profiles and doses of the dopant species. In addition, increasing the doses of the dopant species toward the chemical bonding limit increases the number of charge carrier complexes that can form.

The above theory makes it possible to predict additional cases involving the formation of charge carrier complexes. Prior art laser annealing processes have utilized a preamorphization implant of silicon or germanium to lower the melting temperature of the implanted region. In a first example, the preamorphization implant of silicon or germanium is not required. BF₂ is implanted at a dose of about 5E15 or greater, followed by laser annealing. This results in the formation of B—F complexes, which produce the charge carrier complexes and lower the sheet resistance Rₛ. The melt zone is defined by the pre-amorphizing depth of the BF₂ implant.

In a second example, a preamorphization implant of silicon or germanium, is performed at a dose about 1E15. Then arsenic is implanted at a dose of 1E15 or greater, followed by laser annealing. Initially As₂ complexes form, and activation percent and sheet resistance are limited, because each arsenic dopant atom provides one charge carrier (i.e., two charge carriers per As₂ complex). When As₂ is saturated at a dose of about 1E15, As—Si complexes begin to form, thus providing two charge carriers per arsenic dopant atom.

In a third example, the SPE process is used, but the preamorphization implant of silicon or germanium is not required. BF₂ is implanted at a dose in a range of about 1E14 to 5E15, followed by low temperature annealing. The wafer may be capped with an oxide or a nitride before low temperature annealing to retain the fluorine in the wafer and thereby promote the formation of B—F complexes.

While there have been shown and described what are at present considered the preferred embodiments of the present invention, it will be obvious to those skilled in the art that various changes and modifications may be made therein without departing from the scope of the invention as defined by the appended claims.

1. A method for forming an ultrashallow junction in a semiconductor wafer, comprising the steps of:
introducing into a shallow surface layer of the semiconductor wafer a dopant material that is selected to form charge carrier complexes which produce at least two charge carriers per complex; and
processing the semiconductor wafer containing the dopant material to form said charge carrier complexes.

2. A method as defined in claim 1 wherein the dopant material comprises two species selected to form said charge carrier complexes.

3. A method as defined in claim 1 wherein the dopant material comprises a compound containing two species selected to form said charge carrier complexes.

4. A method as defined in claim 1 wherein the dopant material is selected to chemically bond with atoms of the semiconductor wafer to form the charge carrier complexes.

5. A method as defined in claim 1 wherein the dopant material is selected to form exciton complexes.

6. A method as defined in claim 1 wherein the dopant material is selected from the group consisting of B—F, B—Ge, B—Si, P—F, P—Ge, P—Si, As—F, As—Ge and As—Si.

7. A method as defined in claim 1 wherein the step of introducing a dopant material comprises ion implantation of the dopant material.

8. A method as defined in claim 1 wherein the step of introducing a dopant material comprises plasma doping of the dopant material.

9. A method as defined in claim 1 wherein the step of introducing a dopant material comprises forming multiple doped layers.

10. A method as defined in claim 1 wherein the step of introducing a dopant material comprises gas phase doping.

11. A method as defined in claim 1 wherein the step of introducing a dopant material is part of an epitaxial deposition step.

12. A method as defined in claim 1 wherein the step of introducing a dopant material is part of a chemical vapor deposition step.

13. A method as defined in claim 1 wherein the shallow surface layer has a thickness of 500 angstroms or less.

14. A method as defined in claim 1 wherein the step of processing the semiconductor wafer comprises thermal processing.

15. A method as defined in claim 1 wherein the step of processing the semiconductor wafer comprises laser annealing.

16. A method as defined in claim 1 wherein the step of processing the semiconductor wafer comprises rapid thermal processing.

17. A method as defined in claim 1 wherein the step of processing the semiconductor wafer comprises solid phase epitaxy.

18. A method as defined in claim 1 wherein the step of processing the semiconductor wafer comprises microwave annealing.

19. A method as defined in claim 1 wherein the step of processing the semiconductor wafer comprises radio frequency annealing.

20. A method as defined in claim 1 wherein the step of processing the semiconductor wafer comprises shock wave annealing.

21. A method as defined in claim 1 wherein the step of processing the semiconductor wafer comprises furnace annealing.

22. A method as defined in claim 1 wherein the step of introducing a dopant material comprises introducing two species selected to form said charge carrier complexes and matching the depth and dose profiles of the two species.

23. A method as defined in claim 1 wherein the step of processing the semiconductor wafer comprises rapid thermal processing followed by rapid cooling.

24. A method as defined in claim 1 wherein the dopant material comprises BF₂.

25. A method as defined in claim 1 wherein the dopant material comprises B and Ge.

26. A method for forming an ultrashallow junction in a semiconductor wafer, comprising the steps of:
implanting into a shallow surface layer of the semiconductor wafer one or more dopant materials that are selected to form charge carrier complexes which produce at least two charge carriers per complex; and
thermal processing of the semiconductor wafer to form said charge carrier complexes.

27. A method as defined in claim 26 wherein said dopant material is selected from the group consisting of BF₂ and B—Ge.

28. A method as defined in claim 26 wherein the shallow surface layer has a thickness of 500 angstroms or less.

29. A method as defined in claim 26 wherein said charge carrier complexes comprise exciton complexes.

30. A method for forming an ultrashallow junction in a semiconductor wafer, comprising the step of:
forming in a shallow surface layer of the semiconductor wafer charge carrier complexes which produce at least two charge carriers per complex.

31. A semiconductor device comprising:
a semiconductor substrate; and
a shallow surface layer of the semiconductor substrate containing charge carrier complexes which produce at least two charge carriers per complex, wherein the charge carriers are dissociated from said charge carrier complexes during operation of the semiconductor device.

32. A method for forming an ultrashallow junction in a semiconductor wafer, comprising the step of:
doping a shallow surface layer of the semiconductor wafer with a dopant material that is selected to form charge carrier complexes which produce at least two charge carriers per atom of the dopant material.
